(19) United States
(12) Patent Application Publication
(10) Pub. No.: US 2020/0020649 A1
(43) Pub. Date: Jan. 16, 2020

(54) Cavity based feature on chip carrier

(71) Applicant: Infineon Technologies AG, Neubiberg (DE)

(72) Inventors: Edward Myers, Muenchen (DE); Thomas Bemmerl, Schwandorf (DE); Melissa Stahl, Muenchen (DE)

(21) Appl. No.: 16/578,710

(22) Filed: Sep. 23, 2019

Related U.S. Application Data
(62) Division of application No. 15/582,646, filed on Apr. 29, 2017.

(30) Foreign Application Priority Data
Apr. 29, 2016 (DE) 10 2016 108 060.8

(51) Int. Cl. H01L 23/00; H01L 23/495; H01L 23/31; H01L 21/56; H01L 21/48

(52) U.S. Cl. CPC H01L 23/562; H01L 24/16; H01L 23/49582; H01L 23/49548; H01L 23/4952; H01L 23/49503; H01L 2224/16257; H01L 21/565; H01L 21/4842; H01L 21/4828; H01L 21/4825; H01L 2924/35121; H01L 23/3114

(57) ABSTRACT

A package comprising an electronic chip with at least one electric contact structure, an electrically conductive chip carrier having at least one coupling cavity, and a coupling structure located at least partially in the at least one coupling cavity and electrically contacting the at least one electric contact structure with the chip carrier.

### BACKGROUND OF THE INVENTION

### Field of the Invention

The present invention relates to packages and to methods of manufacturing a package.

### Description of the Related Art

Packages may be denoted as encapsulated electronic chips with electrical connects extending out of the encapsulant and being mounted to an electronic periphery, for instance on a printed circuit board. The package may be connected to the printed circuit board by soldering. For this purpose, solder bumps may be provided at an interior or exterior surface of the package. The interior connection may refer to a chip to chip carrier, and the exterior may refer to connections to the printed circuit board.

Packaging cost is an important driver for the industry. Related with this are performance, dimensions and reliability. The different packaging solutions are manifold and have to address the needs of the application. There are applications, where high performance is required, others, where reliability is the top priority—but all require lowest possible cost.

In particular, reliability of package internal and/or package external solder connections is desired.

### SUMMARY OF THE INVENTION

There may be a need for a package with high reliability.

According to an exemplary embodiment, a package is provided which comprises an electronic chip with at least one electric contact structure, an electrically conductive chip carrier (for instance a completely electrically conductive chip carrier such as a leadframe, which may consist of metallic material) having at least one coupling cavity, and a coupling structure located at least partially in at least one coupling cavity and electrically contacting at least one electric contact structure with the chip carrier (in particular by a solder connection).

According to another exemplary embodiment, a package is provided which comprises an electronic chip with at least one electric contact structure, a (in particular electrically conductive, more particularly exclusively or completely electrically conductive) chip carrier having a first surface portion being geometrically adapted (for instance by the formation of a cavity, or by the provision of another appropriate non-planar shape) to have a higher wettability for coupling material than an adjacent surface, and having a second surface with a higher adhesiveness for encapsulant material than an adjacent surface, a coupling structure located at least partially on the first surface portion and electrically contacting at least one electric contact structure with the chip carrier (in particular by a solder connection), and an encapsulant encapsulating at least part of the electronic chip and covering at least part of the second surface portion.

According to yet another exemplary embodiment, a method of manufacturing a package is provided, wherein the method comprises providing an electronic chip with at least one electric contact structure, providing an electrically conductive chip carrier with at least one coupling cavity, and coupling (in particular electrically conductively coupling, more particularly soldering) a coupling structure at least partially in at least one coupling cavity to thereby electrically contact (or connect) at least one electric contact structure with the chip carrier.

According to still another exemplary embodiment, a method of manufacturing a package is provided, wherein the method comprises providing an electronic chip with at least one electric contact structure, providing an electrically conductive chip carrier with a first surface portion being geometrically adapted (for instance by the formation of a cavity, or by the provision of another appropriate non-planar shape) to have a higher wettability for coupling material than an adjacent second surface portion, and with the second surface portion having a higher adhesiveness for encapsulant material than the adjacent first surface portion, coupling (in particular electrically conductively coupling, more particularly soldering) a coupling structure located at least partially on the first surface portion to thereby electrically contact at least one electric contact structure with the chip carrier, and encapsulating at least part of the electronic chip and the second surface portion by an encapsulant.

According to an exemplary embodiment, a package architecture is provided in which one or more coupling cavities (in particular solder cavities) may be provided as locally limited indentations in a chip carrier. By taking this measure, a coupling structure electrically and mechanically connecting the chip carrier at the position of the respective coupling cavity with a respective electrically conductive connection structure can be forced to remain spatially focused at and around a position of the respective coupling cavity. The reason for this is that the coupling structure will have the tendency to accumulate and remain selectively within the indentation type concave coupling cavity for physical reasons and will not flow in an uncontrolled manner over an entire carrier surface during forming an electric connection (in particular during soldering). Therefore, an electrically conductive connection between a respective electric contact structure of the respective electronic chip and the chip carrier can be rendered more defined and more reliable. The undesired phenomenon of solder bleeding or bleeding of other electrically conductive coupling material can therefore be at least strongly suppressed, since the coupling cavity spatially confines the coupling material within the concave cavity so that an uncontrolled flow of coupling material away from the coupling position of a conductive connection can be prevented or suppressed.

According to another aspect of an exemplary embodiment, a first surface portion may be selectively shaped or configured geometrically so as to promote accumulation and wetting by coupling material selectively in this first surface portion. This can be accomplished for instance by providing one or more cavities in the first surface portion. By taking this measure, solder bleeding and related phenomena can be prevented since the coupling material will have the tendency to accumulate in this first surface portion with its high solder-wettable, sinter-wettable, adhesive-wettable, etc., properties. At the same time, another second surface portion of the electrically conductive chip carrier may be selectively treated or configured so that an encapsulant material provided for encapsulating components of the package will have a locally increased tendency of remaining adhesively connected with the chip carrier in the second surface portion. For example, a mold lock function (in an example in which the encapsulant is configured as a mold compound) may be accomplished in the second surface portion for suppressing undesired delamination between encapsulant and chip carrier. Since the latter provision also prevents cracks in solder joints or other electrically conductive joints, a crack stopper function may be achieved. Therefore, simultaneously with the suppression of uncontrolled distribution of electric connection material (in particular solder bleeding), a precise spatial definition and delamination-free provision of the encapsulant material of the package is enabled.

### DESCRIPTION OF FURTHER EXEMPLARY EMBODIMENTS

In the following, further exemplary embodiments of the packages and the methods will be explained.

In the context of the present application, the term “package” may particularly denote at least one partially or fully encapsulated electronic chip with at least one external electric contact.

The term “electronic chip” may particularly denote a semiconductor chip having at least one integrated circuit element (such as a diode or a transistor) in a surface portion thereof. The electronic chip may be a naked die or may be already packaged or encapsulated.

In the context of the present application, the term “encapsulant” may particularly denote a substantially electrically insulating and preferably thermally conductive material surrounding (preferably hermetically surrounding) an electronic chip and part of a chip carrier to provide mechanical protection, electrical insulation, and optionally a contribution to heat removal during operation. Such an encapsulant can be, for example, a mold compound or a laminate.

In the context of the present application, the term “electric contact structure” may particularly denote an electrically conductive contact forming part of the electronic chip before and after assembly of the package. Thus, this term relates to electrically conductive structures of the package which have already been part of the electronic chip even before establishing a solder, sinter, conductive adhesive, or other electrically conductive connection between the electronic chip and the chip carrier.

In the context of the present application, the term “coupling cavity” may particularly denote a concave indentation or recess being formed locally, limited at a certain position of the chip carrier in which, in a readily manufactured package, corresponding coupling material providing for an electric connection of at least one electric contact structure of the electronic chip is at least partially located. In other words, the provision of one or more cavities of a chip carrier may be limited to one or more positions at which one or more electric contact structures of the respective at least one electronic chip is located after having established a conductive connection between the respective electronic chip and the chip carrier. Preferably, other surface portions of the chip carrier may remain free of cavities. The shape and the dimension of at least one coupling cavity may be specifically configured so as to suppress bleeding of conductive material upon establishing a conductive connection between at least one electric contact structure and the chip carrier at the position of the respective coupling cavity. Therefore, the order of magnitude of the dimension of at least one coupling cavity may correspond to the order of magnitude of a corresponding coupling structure.

In the context of the present application, the term “coupling structure” may particularly denote a solderable, sinterable or conductive and adhesive material, for example comprising or consisting of tin, etc. In particular such a solderable material may have the physical property that, at typical solder temperatures, in particular in a range between 150° C. and 300° C., the material of the coupling structure may re-melt for establishing a solder connection between the respective electric contact structure and the respective coupling cavity or first surface portion of the chip carrier. Similar processing may occur upon sintering, forming connections using electrically conductive adhesive, etc.

In the context of the present application, the term “higher wettability” may particularly denote that the corresponding first surface portion of the chip carrier has a higher tendency of being wetted by coupling material than another surface of the chip carrier. In other words, the first surface portion may have pronounced wettable properties for the coupling material. For instance, a higher wettability of the first surface portion may be obtained by cleaning the surface prior to forming the electrically conductive connection, adjusting smoothness of the surface, and/or plating material (such as silver, gold, nickel, palladium, platinum, nickel-phosphor (NiP), organic surface protection (OSP), and/or tin) on the surface.

In the context of the present application, the term “higher adhesiveness” may particularly denote that the surface properties of the second surface portion may be specifically configured so that, locally in this second surface portion, the adhesion force between the chip carrier and an encapsulant encapsulating the second portion of the chip carrier is higher than an adhesion force between encapsulant material and chip carrier in another surface of the chip carrier surrounding the second surface portion. Thus, the locally-limited increase of the encapsulant adhesion properties of the surface of the chip carrier in the second surface portion may be denoted as higher adhesiveness. This may be accomplished, for instance, for selectively roughening the surface and/or by plating the surface with an adhesion increasing material.

In an embodiment, the coupling structure comprises a solder structure, an electrically conductive adhesive, and/or a sinter structure. The formation of an electrically conductive connection with any of these coupling structures in connection with a cavity or any other corresponding geometrical adaptation of the carrier surface may provide for an improved coupling independently of what material is used to make the electric contact. Although embodiments of the invention may be carried out with any of the mentioned materials of the coupling structure, the following description focuses, for the sake of conciseness, on solderable material as coupling structure. However, a person skilled in the art will understand that the following embodiments may also be applied to other coupling structures.

In an embodiment, the electronic chip is mounted on the chip carrier in flip chip configuration. In this context, the term “flip-chip configuration” may particularly denote an upside down or face down orientation of the electronic chip with regard to the chip carrier. In other words, an active region and corresponding electric contact structures of the electronic chip may be provided (at least also) at a main surface of the electronic chip facing a corresponding main surface of the chip carrier. Thus, the connection between the above-mentioned at least one electric contact structure and the chip carrier may be established by the coupling structure rather than by a bond wire configuration. An exemplary embodiment provides a corresponding assembly architecture in which undesired solder bleeding is advantageously suppressed.

In an embodiment, at least part of a surface of at least one coupling cavity comprises at least one of the following surface finishes: a solder-promoting plating (in particular comprising tin), a solder-promoting configuration of a bare metal surface (in particular a bare copper surface, more particularly with a smoother surface than a rougher surface surrounding the coupling cavity or first surface portion), a solder-promoting pre-plating, and a solder-promoting deposited material. More generally, the respective solder-promoting measure may be any type of electric connection-promoting measure, when another type of coupling (such as sintering, or using an electrically conductive adhesive) is implemented instead of soldering. For instance, plating a coupling cavity with solderable material (in particular tin plating) may further improve the quality of the solder connection in particular to provide for a “solder-on-solder” connection. With the described provisions, which can be implemented individually or in any desired combination, locally increased wettability in the coupling cavity or in the first surface portion may be obtained.

In an embodiment, the package comprises an encapsulant, in particular a mold compound, encapsulating at least part of the electronic chip and at least part of the chip carrier. Such an encapsulant may mechanically protect the electronic chip and may electrically decouple the electronic chip-chip carrier arrangement at least in the region of the respective solder connection with regard to an environment. As an alternative to a mold encapsulation, an encapsulation via a laminate is possible.

In an embodiment, at least part of a surface of the chip carrier encapsulated by the encapsulant is configured to have a higher adhesiveness for material of the encapsulant than an adjacent surface. By such a locally increased adhesiveness at the connection between chip carrier and mold compound, the undesired tendency of delamination or the like can be suppressed. Therefore, the electrical and mechanical reliability can be increased. In particular, leakage currents may be suppressed and the disruptive strength of the package may be improved.

In an embodiment, at least part of the surface with the locally higher adhesiveness comprises at least one of the following surface finishes: an adhesion promoting configuration of a bare metal surface (in particular of a bare copper surface), an adhesion promoting pre-plating, and an adhesion promoting roughened surface (for instance by roughening the second surface portion by microetching, plating a rough layer, etc.). Any of the mentioned provisions for locally increasing adhesiveness between chip carrier and encapsulant can be applied individually or in any desired combination at the second surface portion of the chip carrier apart from the solder cavities/first surface portion.

In an embodiment, at least one electric contact structure comprises a pad. Such a pad may be an electrically conductive flat structure which is arranged in a surface portion of a bare die as an electric interface between integrated circuit elements monolithically integrated in an interior of the electronic chip and the chip carrier. For example, a pad may be made of copper, gold, etc.

In an embodiment, at least one electric contact structure comprises an electrically conductive pillar or post, in particular a pillar on a pad of the at least one electric contact structure. Such a pillar may be, for instance, a cylindrical or post-shaped or pin-shaped electrically conductive element which protrudes beyond a surface of the respective electronic chip. A copper pillar may be directly in contact with a respective chip pad. In view of its protruding geometry, such a pillar (which may be made of copper) provides a proper basis for extending up to or into the respective coupling cavity for contributing to a reliable solder connection.

In an embodiment, the coupling structure comprises a plated cap on the pillar. By configuring a cap or end portion of the pillar as solderable material, the coupling structure may be realized at an integrally formed structure of the electronic chip. Therefore, the assembly process can be simplified. For instance, the solder cap may be a solderable material such as tin which may be provided for example as a hemispherical structure on a circular cylindrical pillar (for instance of copper material).

Alternatively, the pillar may be configured without integrated cap, i.e. may be free of a solderable cap. When the pillar does not have a solder cap, solder material or any other form of conductive adhesive, sinterable material, etc. can be provided within the cavity.

In an embodiment, the coupling structure comprises a solder bump. A solder bump may be a bulky structure of solderable material such as tin which forms a bridge between the coupling cavity or first surface portion on the one hand and the respective electric contact structure of the electronic chip on the other hand. It may be applied onto the electric contact structure or onto the coupling cavity or first surface portion of the chip carrier prior to the assembly of the package.

In an embodiment, the coupling structure located in one coupling cavity electrically contacts at least two pillars (or other separate electrically conductive bodies) of at least one electric contact structure with the chip carrier, in particular at least two pillars (or other separate electrically conductive bodies) on a common pad of at least one electric contact structure. By assigning multiple pillars or the like to one coupling cavity and/or to one pad, the efficient surface area between pillar and coupling material can be increased, thereby rendering the solder connection even more reliable from an electric and mechanical point of view. Such a multi-pillar structure may also be capable of transporting a higher current.

In an embodiment, the coupling structure partially extends beyond at least one coupling cavity, in particular in at least one of a horizontal direction and a vertical direction. While a major portion of the coupling structure may be located within the coupling cavity after completion of the solder connection, it is possible that, upon establishing the solder connection, a portion of the coupling material is pressed out or remains out of the coupling cavity. Thus, some excess of coupling material may be provided ensuring that a major portion of the coupling cavity remains filled with coupling material after having established the solder connection.

In an embodiment, the chip carrier is configured as a leadframe. A leadframe may be a metal structure inside a chip package that is configured for carrying signals from the electronic chip to the outside, and/or vice versa. The electronic chip inside the package may be attached to the leadframe for establishing an electric connection between the electronic chip and leads of the leadframe. Subsequently, the leadframe may be molded in a plastic case or any other encapsulant. Outside of the leadframe, a corresponding portion of the leadframe may be cut-off, thereby separating the respective leads. Before such a cut-off, other procedures such a plating, final testing, packing, etc. may be carried out, as known by those skilled in the art. Leadframe or chip carrier can be coated before encapsulation, for instance by an adhesion promoter.

In an embodiment, a surface portion of the chip carrier facing the electronic chip is substantially planar except at the at least one coupling cavity. Therefore, the chip carrier may be manufactured as a flat plate like or sheet shaped structure having selective dimples or indentations as solder cavities limited to surface portions of the chip carrier, at which a solder connection with the respective electric contact structures of the one or more electronic chips shall be established.

In an embodiment, at least one coupling cavity delimits a fully rounded surface portion of the chip carrier. With such a rounded, continuous boundary surface without narrow edges, steps or other discontinuities, coupling material may homogeneously wet, without interruption, a connected cavity surface. This promotes the reliability of the solder connection.

In an embodiment, the package comprises a further electronic chip with at least one further electric contact structure, and a further coupling structure located at least partially in at least one further coupling cavity and electrically contacting at least one further electric contact structure with the chip carrier by an electrically conductive connection such as a further solder connection. Therefore, it is possible that multiple electronic chips, for instance multiple semiconductor chips are encapsulated within the same package and connected to the same chip carrier. Therefore, the solder architecture according to exemplary embodiments of the invention is compatible also with multi-chip configurations.

In an embodiment, the first surface portion forms at least part of a coupling cavity. While the first surface portion may correspond to at least one coupling cavity, the second surface portion may be provided separately from the solder cavities.

In an embodiment, at least one coupling cavity is formed by at least one of the groups consisting of etching and stamping. These manufacturing methods of forming the one or more solder cavities are simple and reliable. However, other manufacturing methods are possible as well.

In an embodiment, the coupling structure has a larger lateral extension than a corresponding one of at least one coupling cavity prior to the soldering. By taking this measure, a sufficient degree of filling of a coupling cavity by a coupling material after having formed the solder connection may be ensured. This has a positive impact on the reliability of the manufactured package.

In an embodiment, the encapsulant comprises or consists of at least one of the group consisting of a mold compound and a laminate.

In an embodiment, the encapsulant comprises a laminate, in particular a printed circuit board laminate. In the context of the present application, the term “laminate structure” may particularly denote an integral flat member formed by electrically conductive structures and/or electrically insulating structures which may be connected to one another by applying a pressing force. The connection by pressing may be optionally accompanied by the supply of thermal energy. Lamination may hence be denoted as the technique of manufacturing a composite material in multiple layers. A laminate can be permanently assembled by heat and/or pressure and/or welding and/or adhesives.

In another embodiment, the encapsulant comprises a mold, in particular a plastic mold. For instance, a correspondingly encapsulated chip may be provided by placing the electronic chip soldered onto the chip carrier (if desired together with other components) between an upper mold die and a lower mold die and to inject liquid mold material therein. After solidification of the mold material, the package formed by the encapsulant with the electronic chip and the chip carrier in between is completed. If desired, the mold may be filled with particles improving its properties, for instance its heat removal properties.

In an embodiment, the method further comprises providing a flux in the at least one coupling cavity for activating a surface of the chip carrier in at least one coupling cavity prior to soldering the coupling structure in the at least one coupling cavity. The concave geometry of at least one coupling cavity hereby supports the controlled supply of the flux selectively on the solder surface in the coupling cavity. Undesired spreading of flowable flux in other surface portions of the chip carrier may therefore be safely prevented. Furthermore, the amount of required flux can be reduced.

In an embodiment, the one or more electronic chips of a package is a/are power semiconductor chip(s). In particular for power semiconductor chips, electric reliability and mechanical integrity are important issues which can be met with the described manufacturing procedure. Possible integrated circuit elements which can be monolithically integrated in such a semiconductor power chip are field effect transistors (such as insulated gate bipolar transistors or metal oxide semiconductor field effect transistors) diodes, etc. With such constituents, it is possible to provide packages for automotive applications, high-frequency applications, etc. Examples for electric circuits which can be constituted by such and other power semiconductor circuits and packages are half-bridges, full bridges, etc.

As substrate or wafer for the semiconductor chips, a semiconductor substrate, for example a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

The above and other objects, features and advantages of the present invention will become apparent from the following description and the appended claims, taken in conjunction with the accompanying drawings, in which like parts or elements are denoted by like reference numbers.

### BRIEF DESCRIPTION OF THE DRAWINGS

The accompanying drawings, which are included to provide a further understanding of exemplary embodiments of the invention and constitute a part of the specification, illustrate exemplary embodiments of the invention.

In the drawings:

FIG. 1 illustrates a cross-section of a package according to an exemplary embodiment.

FIG. 2 to FIG. 4 illustrate cross-sections of structures obtained during carrying out a method of manufacturing a package according to an exemplary embodiment.

FIG. 5 illustrates a cross-section of a part of a package according to an exemplary embodiment.

FIG. 6 illustrates a cross-section of an intermediate structure obtained during manufacturing a package according to an exemplary embodiment.

FIG. 7 illustrates a cross-section of another intermediate structure obtained during manufacturing a package according to an exemplary embodiment.

FIG. 8 and FIG. 9 illustrate cross-sections of intermediate structures obtained during manufacturing a package according to an exemplary embodiment.

FIG. 10 illustrates a cross-section of a package according to an exemplary embodiment.

FIG. 11 shows a package according to yet another exemplary embodiment in which two electronic chips are mounted on a common chip carrier having multiple solder cavities.

FIG. 12 is a plane view of a rectangular coupling cavity and a circular coupling cavity in a respective chip carrier in combination with a group of parallel pillars according to exemplary embodiments of the invention.

FIG. 13 shows a portion of a chip carrier with a coupling cavity in which flux has been dispensed to promote a subsequent solder connection according to an exemplary embodiment.

FIG. 14 illustrates a cross-section of a structure obtained during carrying out a method of manufacturing a package according to an exemplary embodiment.

FIG. 15 illustrates a cross-section of a part of a package according to an exemplary embodiment formed in accordance with FIG. 14.

### DETAILED DESCRIPTION OF EXEMPLARY EMBODIMENTS

The illustration in the drawing is schematically drawn and not to scale.

Before exemplary embodiments are described in more detail referring to the figures, some general considerations will be summarized based on which exemplary embodiments have been developed.

According to an exemplary embodiment of the invention, cavity based flip chip soldering may be implemented. This may allow to overcome a conventional shortcoming related to the phenomenon of solder bleed out of flip chip die attach systems. The mentioned embodiment of the invention addresses the technical challenge that a leadframe surface should preferably offer a trade-off between good wetting, control of the solder bleed out, and a good adhesion to the mold compound.

Consequences of uncontrolled solder bleed out may be at least one of inconsistent bond line thickness, variation in solder joint quality and/or reliability, variation in mold compound adhesion to leadframe (next to solder joint) due to different material interfaces, etc.

In order to overcome one or more of the above shortcomings, an exemplary embodiment of the invention may suppress or at least control solder bleed out of a flip chip die attach process. In particular, a flip chip solder interconnect may be provided with consistent solder volume (covering bond line thickness and bleed out zone). An exemplary embodiment provides two defined levels on the leadframe:

Level 1: surface treatment for promoting soldering,

Level 2: surface tuning for promoting adhesion between mold compound and leadframe.

According to an exemplary embodiment, one or more leadframe dimples or solder cavities may be formed (Level 1) in which a flip chip solder joint may be formed. Cavity or dimple finish may involve one or more of the following measures:

plating (for example provision of local plating depots of tin or other solderable material)

solder deposition/dispensing in form of solder paste into the cavity-provision of a bare copper surface portion

pre-plating

According to another exemplary embodiment of the invention (which can be provided separately from or combined with the previously described embodiment), a proper leadframe finish (Level 2) made involve one or more of the following measures:

provide a bare copper surface

pre-plate with appropriate adhesion promoter material

provide roughened copper or selectively roughened copper

Instead of allowing the solder die attach material to spread, the solder die attach may focus on preferred solder areas of the leadframe according to an exemplary embodiment of the invention.

It is also possible that the volume concentration of coupling material can be reached by form fitting of chip-based solder interconnect into defined leadframe positions. Advantageously, it is possible that typical variations in solder joint volume do not result in solder bleed out as the coupling material may stay inside the coupling cavity. In particular, different solder filling heights may be the consequence of different solder joint volumes. Further advantageously, a self-centering effect may be obtained during a die attach process which may ensure that a center of solder joints may be placed in the center of solder dimples or cavities. Moreover, solder joint robustness may be enhanced compared to planar solder joints (for example where a copper pillar is sitting on a planar leadframe). It is possible that one or more vertically recessed solder joints are provided (i.e. a material locking of coupling material inside a dimple), which may support the solder joint locking with the leadframe, and which may also disrupt a potential package delamination path along a planar surface.

Beyond this control of die attach solder bleed out on leadframe area, a further measure (Level 2) may allow for a defined material interface from mold compound to leadframe, which may result in consistent adhesion quality.

Exemplary embodiments of the invention can be applied in particular to the following (but also to other) flip chip (or non-flip chip) types:

pillar-type (for example a copper pillar with plated pillar top) or

pre-assembled with solder bumps

copper pillar without solder top

According to an embodiment, a leadframe having one or more solder cavities can be manufactured, for example, by an etching and/or a stamping process.

Hence, an exemplary embodiment of the invention provides a leadframe with one or more solder dimples which may be a kind of leadframe cavity, being the pre-defined solder interconnect target area for copper pillars or solder bumps.

In an embodiment, the provision of a leadframe with one or more solder cavities can be applied to a single chip in package architecture and for a multi-chip in package configuration.

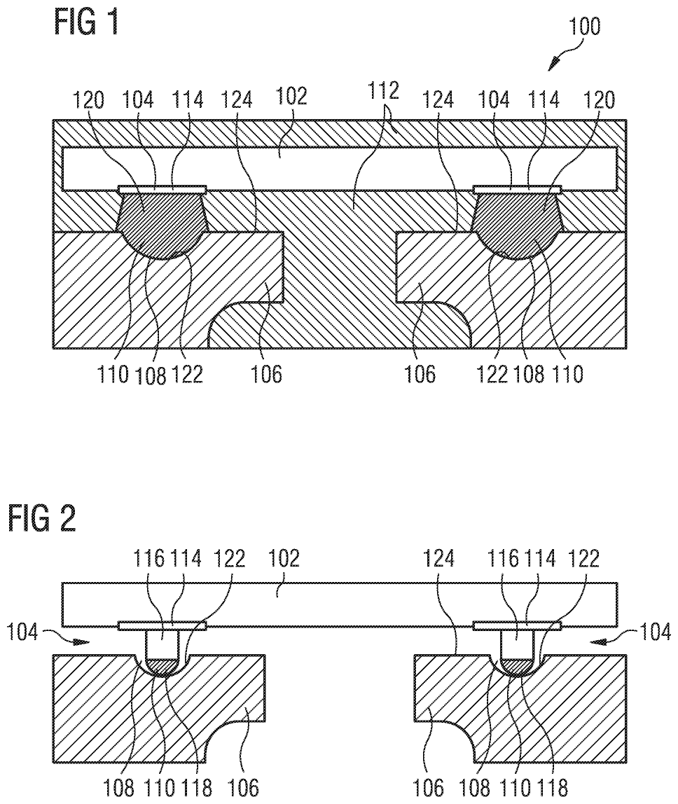

FIG. 1 illustrates a cross-section of a package 100 according to an exemplary embodiment.

The package 100 comprises an electronic chip 102, for instance a power semiconductor chip, with electric contact structures 104 for electrically contacting integrated circuit elements of the electronic chip 102 with regard to an electronic periphery. Each of the electric contact structures 104 comprises a chip pad 114. As can be taken from FIG. 1, the electronic chip 102 is mounted on a chip carrier 106 in flip chip configuration, i.e. face down. In other words, an active chip region with one or more integrated circuit elements (not shown) is located in a bottom surface of the electronic chip 102 according to FIG. 1.

Furthermore, the electrically conductive chip carrier 106, here embodied as a leadframe which consists of copper, is provided as part of the package 100 and comprises coupling cavities 108, one for each electric contact structure 104. As can be taken from FIG. 1, each of the coupling cavities 108 delimits a respective concave surface portion of the chip carrier 106. In other words, an internal contour of a border between coupling cavity 108 and chip carrier 106 is continuous which promotes undisturbed wetting of the first surface portion by solderable material (as described in the following referring to coupling structures 110).

Each of multiple coupling structures 110, here embodied as solder bumps 120 which may for instance comprise or consist of tin, is located partially in a respective coupling cavity 108 and is partially located above a respective coupling cavity 108 to extend up to the respective contact structure 104. The coupling structures 110 are hence provided for electrically contacting a respective electric contact structure 104 with the chip carrier 106 by a solder connection. As shown in FIG. 1, the coupling structures 110 partially extends beyond the respective coupling cavity 108 in both a horizontal direction and a vertical direction.

The electrically conductive chip carrier 106 has a first surface portion 122 defined by the coupling cavities 108 having a higher wettability for coupling material than an adjacent second surface portion 124 having a higher adhesiveness for material of a mold-type encapsulant 112 than the first surface portion 122. The first surface portion 122 corresponds to the concave coupling cavities 108. The second surface portion 124 of the chip carrier 106 facing the electronic chip 102 is substantially planar. The surface specific functions (promoting soldering, promoting adhesion of mold compound) can be achieved by a combination of shape, material and surface treatment of the first surface portion 122 and of the second surface portion 124.

FIG. 1 shows that the package 100 furthermore comprises the above-mentioned encapsulant 112, which may be configured as a mold compound, encapsulating the electronic chip 102 and the contact structures 104 and covering the second surface portion 124 of the chip carrier 106.

The first surface portion 122 corresponding to the coupling cavities 108 may be treated in accordance with one or more of the following surface finishes in order to specifically and locally increase wettability of the first surface portion 122 by coupling material:

a solder-promoting plating, in particular comprising tin;

a solder-promoting treatment of a bare metal surface, in particular a bare copper surface; and/or

a solder-promoting pre-plating.

The second surface portion 124, covered by the encapsulant 112 may be equipped with a locally increased adhesiveness for material of the encapsulant 112 in accordance with one or more of the following surface finishes:

an adhesiveness-promoting treatment of a bare metal surface, in particular a bare copper surface;

an adhesiveness-promoting pre-plating; and/or

an adhesiveness-promoting roughened surface.

In the embodiment according to FIG. 1, package 100 comprises a single electronic chip 102 embedded in a mold compound as encapsulant 112. The leadframe type chip carrier 106 has two dimples or indentations as coupling cavities 108 in a main surface thereof facing a corresponding main surface of the flip-chip type assembled electronic chip 102. The coupling structure 110 is configured as solder bump 120, but can also be a solder ball or a solder depot. As can be taken from FIG. 1, the coupling structure 110 completely fills the coupling cavities 108 thereby establishing a solder connection with the electric contact structures 104 of the electronic chip with a substantially constant cross-section in a vertical direction.

FIG. 2 to FIG. 4 illustrate cross-sections of structures obtained during carrying out a method of manufacturing a package 100 according to an exemplary embodiment.

Referring to FIG. 2, each of the electric contact structures 104 comprises a copper pillar 116 attached on a respective pad 114. Furthermore, the coupling structure 110 comprises a plated cap 118 integrally formed on the pillar 116.

FIG. 2 shows how the electronic chip 102 with copper pillars 116 bridging the pads 114 with regard to solder caps 110 are inserted into the coupling cavities 108 of the chip carrier 106 prior to soldering.

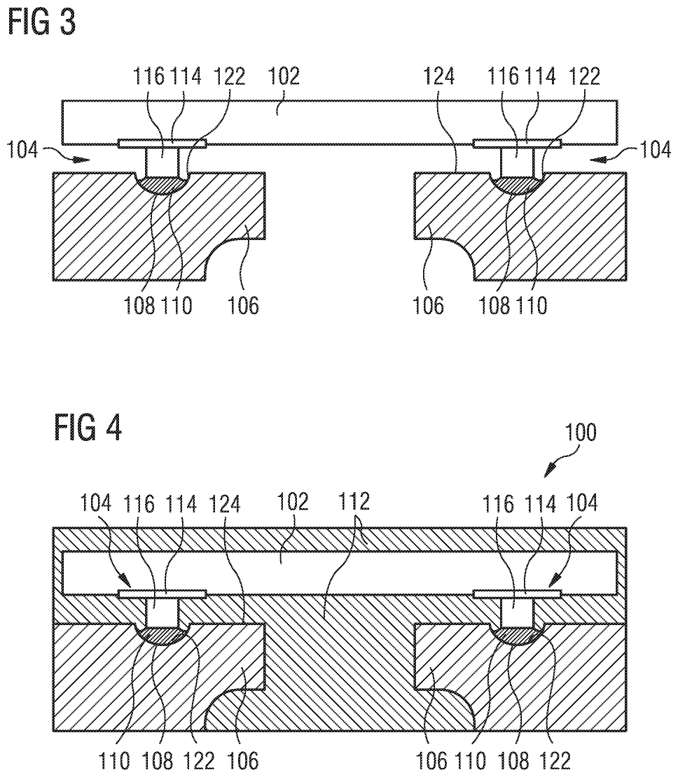

As shown in FIG. 3, a die attach procedure is then carried out by temporarily liquefying or melting the coupling structure 110, for instance by placing the arrangement according to FIG. 2 in a solder oven. Thereby, the material of the coupling structure 110 melts and reflows so as to wet a significant surface portion within the coupling cavities 108. In view of the locally increased wettability capability of the first surface portion 122 of the chip carrier 106 within the coupling cavities 108, the coupling material tends to wet a large surface area within the coupling cavities 108 and is prevented from undesirably flowing into the adjacent second surface portion 124 with intentionally poor wettability capability. As can be taken from FIG. 3, the void volume of the respective coupling cavity 108 is only partially filled with material of the coupling structure 110 and with material of pillar 116, whereas a remaining empty volume of the respective coupling cavity 108 remains even after having established the solder connection. FIG. 4 shows the structure according to FIG. 3 after molding, i.e. after encapsulating the electronic chip 102 as well as its solder connection by molds material. Thanks to the locally increased adhesiveness for encapsulant material in the second surface portion 124, a delamination-free connection between encapsulant 112 and carrier 106 in the second surface portion 124 is obtained.

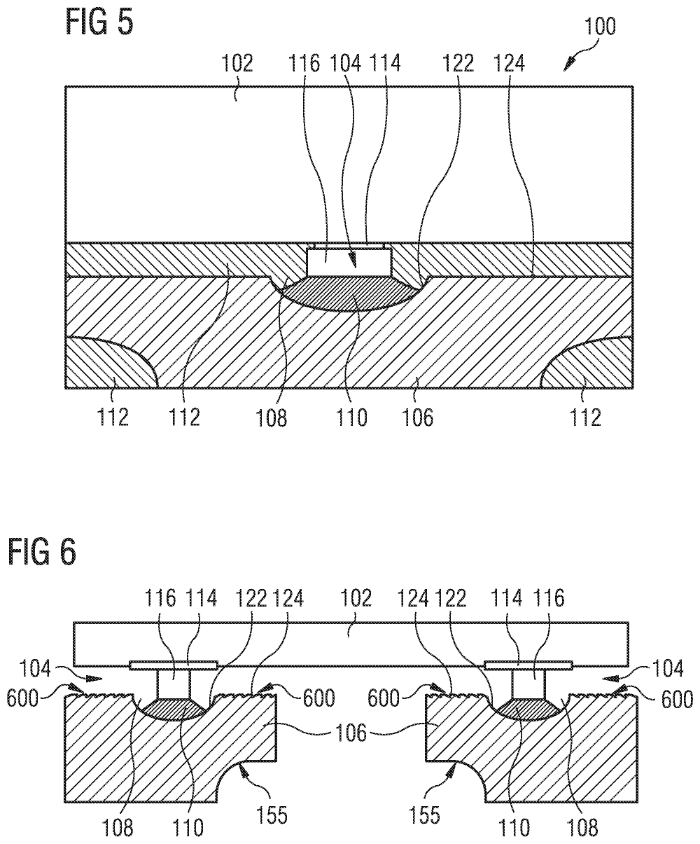

FIG. 5 illustrates a cross-section of a part of a package 100 according to an exemplary embodiment.

In FIG. 5, the pronounced tendency of the coupling material to wet a large surface portion of the coupling cavity 108 can be seen particularly well. In view of the locally increased wettability, the coupling material tends to cover a large surface in the coupling cavity 108.

FIG. 6 illustrates a cross-section of an intermediate structure obtained during manufacturing a package 100 according to an exemplary embodiment.

As can be taken from FIG. 6, an upper main surface of the chip carrier 106 has been selectively roughened. For instance, the surface roughness in this selectively roughened surface portion 600, corresponding to the second surface portion 124, can be for example a microroughness and/or a nanoroughness. However, as can be taken from FIG. 6 as well, the first surface portion 122 relating to the coupling cavities 108 has not been roughened. Roughening the surface portion 600 can be accomplished for example by microetching or by plating a rough layer. The selectively roughened surface 600 only outside of the coupling cavities 108 may be obtained by firstly roughening the entire top surface of the chip carrier 106, followed by the formation of the coupling cavities 108 for example by etching so that no selective roughening procedure needs to be implemented. Thereby, the roughening procedure can be carried out in a simple and quick way.

The configuration of FIG. 6 relates to a roughened leadframe with consequently improved delamination performance. Therefore, it is possible to apply two surface finishings to the package 100 during manufacture, i.e. mold compound locking by selective surface roughening, and solder control by formation of coupling cavities 108.

As can be furthermore taken from FIG. 6, the chip carrier 106 is provided with a locking feature 155 on the lower side which may be formed for example by half etching. Locking feature 155 ensures that material of mold-type encapsulant 112 also moves under the leadframe-type chip carrier 106 (compare for instance FIG. 4), which suppresses undesired delamination of the encapsulant 112 from the chip carrier 106.

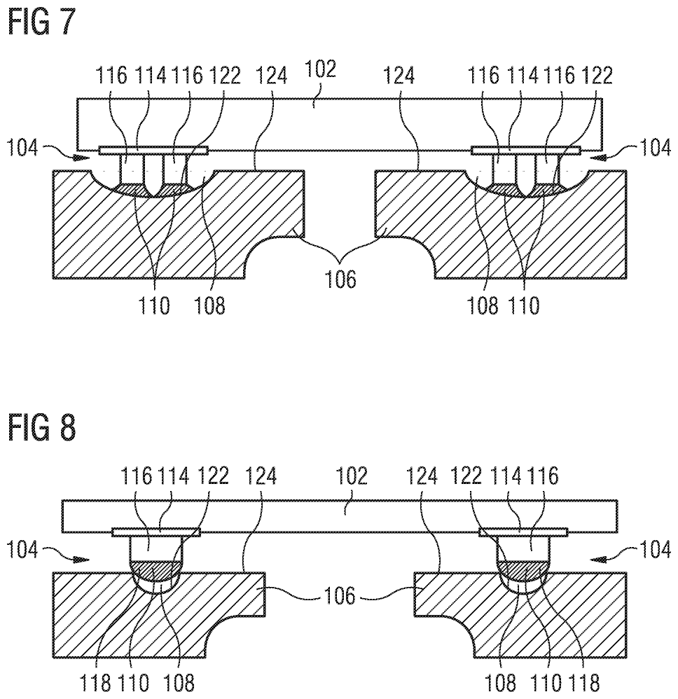

FIG. 7 illustrates a cross-section of another intermediate structure obtained during manufacturing a package 100 according to an exemplary embodiment.

In the embodiment according to FIG. 7, the coupling structure 110 located in one coupling cavity 108 electrically contacts two pillars 116 of the respective electric contact structure 104 with the chip carrier 106. The two pillars 116 per electric contact structure 104 and per coupling cavity 108 are integrally formed on a common pad 114 of the respective electric contact structure 104.

In the multiple pillar architecture per cavity according to FIG. 7, several (in the shown example two) pillars 116 are provided for a single or multi-pad 114 fitting into a single coupling cavity 108. This allows for a close standoff. Moreover, providing multiple pillars 116 for a coupling cavity 108 allows for a higher current flow during operation and/or for a better thermal heat removal.

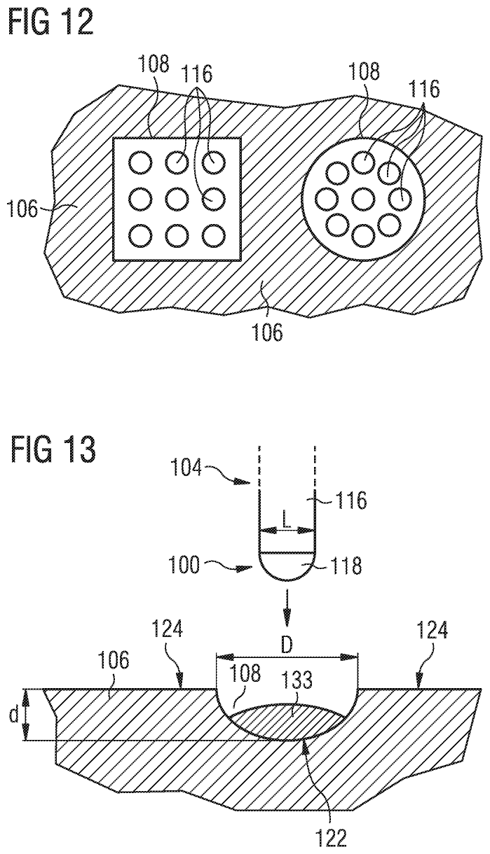

In another embodiment, it is possible to have even more than two pillars 116 per electric contact structure 104 and per coupling cavity 108. For example, it is possible to have a two-dimensional matrix-like pattern of pillars per electric contact structure 104 and per coupling cavity 108 (see for instance FIG. 12).

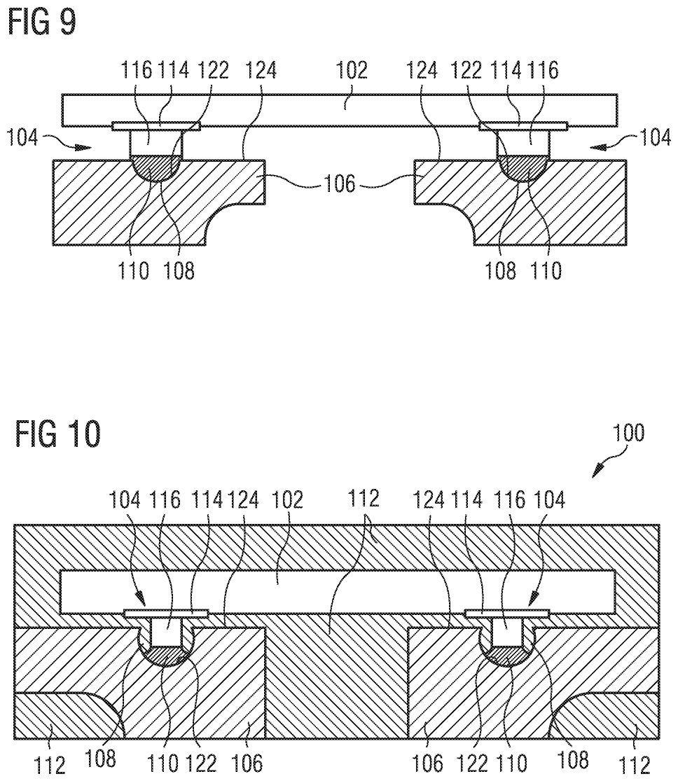

FIG. 8 and FIG. 9 illustrate cross-sections of intermediate structures obtained during manufacturing a package 100 according to an exemplary embodiment.

FIG. 8 and FIG. 9 shown an architecture in which an electronic chip 102 is provided with copper pillars 116, wherein the respective coupling cavity 108 is smaller than the diameter of the pillar 116. Therefore, as shown in FIG. 8, the pillar 116 and the assigned pillar cap do not fit entirely into the coupling cavity 108 in a lateral direction. In other words, the diameter of the hemispherical pillar cap 110 may be larger than a diameter of the coupling cavity 108. As can be taken from FIG. 9, this results in a void-free filling of the coupling cavity 108 with coupling material after having established the solder connection.

FIG. 10 illustrates a cross-section of a part of a package 100 according to an exemplary embodiment.

FIG. 10 shows a detail of an electronic chip 102 with copper pillar 116 architecture after die attach, molding and singulation. According to FIG. 10, the coupling cavity 108 is closer to a full circle than a hemisphere.

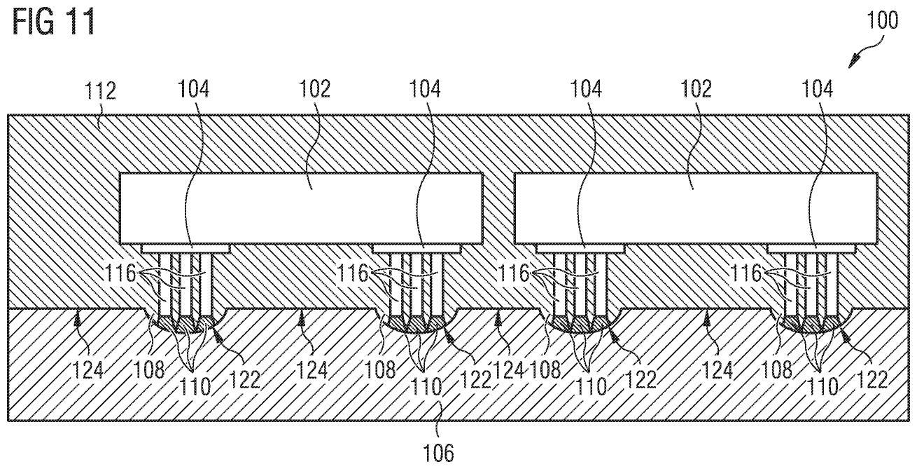

FIG. 11 shows a package 100 according to yet another exemplary embodiment of the invention in which two electronic chips 102 are mounted both in flip chip architecture on a leadframe type chip carrier 106 and being solder connected using the above-described coupling cavity concept.

In addition to the above-described electronic chip 102, package 100 according to FIG. 11 hence comprises a further electronic chip 102 with further electric contact structures 104. Moreover, further coupling structures 110 are provided which are located in further coupling cavities 108 and which electrically contact the further electric contact structures 104 with the chip carrier 106 by a further solder connection. Multiple electrically conductive pillars 116 are provided, in the shown embodiment three per coupling cavity 108. FIG. 11 hence illustrates that the described coupling cavity principle is applicable to any desired number of pillars 116 per coupling cavity 108, and can be applied to a single chip-per-package architecture or a multiple chip-per-package architecture.

FIG. 12 is a plane/top view of a rectangular coupling cavity 108 and a circular coupling cavity 108 in a respective chip carrier 106 in combination with a group of parallel pillars 116 according to exemplary embodiments of the invention.

FIG. 12 illustrates that a coupling cavity 108 according to an exemplary embodiment of the invention can be implemented in very different geometrical shapes. Possible shapes are a circular perimeter, an oval perimeter, or any polygonal perimeter (such as a rectangular or even square perimeter, a hexagonal perimeter, or the like) with sharp or rounded corners.

As can be taken from FIG. 12, an array of pillars 116 may be located in each of the coupling cavities 108. Such an array may be a matrix-like arrangement with rows and columns (as shown on the left-hand side of FIG. 12), or a central pillar 116 with one or more surrounding rings of pillars 116 (shown on the right hand side of FIG. 12). Other types of pillars 116 or conductive bodies with other shape are of course possible.

FIG. 13 shows a portion of a chip carrier 106 with a coupling cavity 108 in which flux 133 has been dispensed to promote a subsequent solder connection according to an exemplary embodiment.

Dispensing or dotting one or more drops of flux 133 into a coupling cavity 108 may be carried out prior to a die attach procedure, i.e. prior to soldering a coupling structure 110 (for instance a plated cap 118 on a pillar 116 of a contact structure 104) onto a surface of the chip carrier 106 in the first surface portion 122 corresponding to coupling cavity 108. The provision of flux 133 promotes the formation of a solder connection. Highly advantageously, the concave geometry of coupling cavity 108 forces the dispensed flowable flux 133 to remain within coupling cavity 108 rather than being distributed over a wider and uncontrolled surface area of the chip carrier 106. Thus, the coupling cavity 108 holds or spatially concentrates the flux 133 without flux spreading. The flux 133 may activate the (for instance copper) surface of the chip carrier 106 and may thus function as a wetting promoter. In other words, the flux 133 may clean the copper surface to promote soldering.

FIG. 13 also illustrates a horizontal width, D, and a vertical depth, d, of the coupling cavity 108. Also a typical width, L, of pillar 116 is shown. Advantageously, horizontal width, D, may be larger than vertical depth, d. Hence, the coupling cavity/cavities 108 may be broader than deep, for instance may have a semielliptical shape in a cross-sectional view. For example, horizontal width, D, may be in a range between 20 μm and 1000 μm, in particular in a range between 50 μm and 200 μm. The actual dimension of horizontal width, D, may also depend in particular on the width, L, of pillar 116 and on the number of pillars 116 per coupling cavity 108. For instance, the width, L, of pillar 116 may be in a range between 20 μm and 200 μm, in particular between 50 μm and 150 μm. Vertical depth, d, of coupling cavity 108 may be in a range between 3 μm and 100 μm, in particular in a range between 5 μm and 30 μm. When the coupling cavity 108 becomes too shallow, some remaining solder bleed may occur. When the coupling cavity 108 becomes too deep, issues concerning chip underfill may arise.

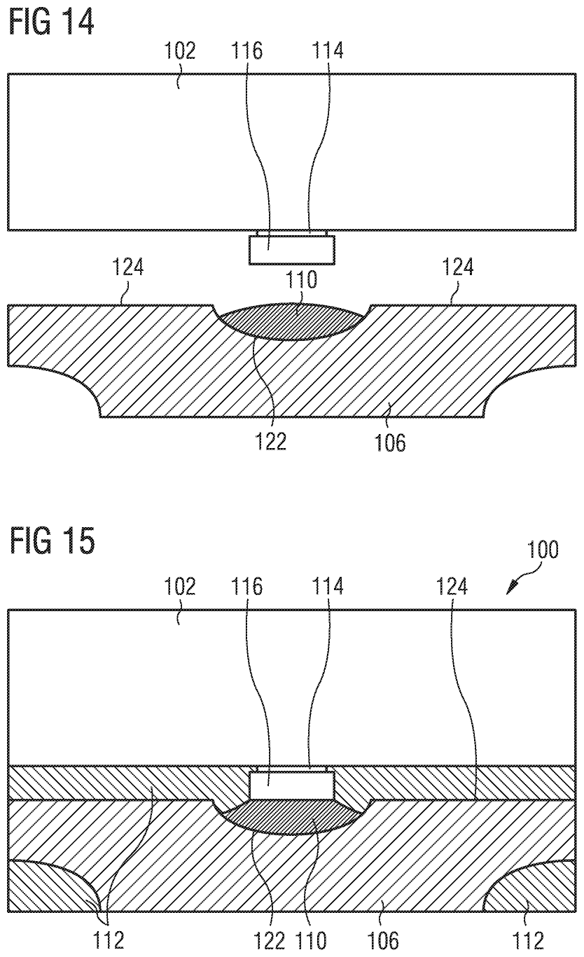

FIG. 14 illustrates a cross-section of a structure obtained during carrying out a method of manufacturing a package 100 according to an exemplary embodiment. In the structure according to FIG. 14, a copper pillar 116 (without solder cap 118) is connected via a pad 114 to the electronic chip 102. A coupling structure 110, which may for instance be embodied as solder paste, an electrically conductive adhesive, or a sinterable material, is placed inside the cavity 108 corresponding to the first surface 122. FIG. 15 illustrates a cross-section of a part of a package 100 according to an exemplary embodiment formed based on the structure shown in FIG. 14 after die attach and molding.

In the following, various exemplary aspects of a package according to the present invention are summarized:

Aspect 1: A package, comprising:
an electronic chip with at least one electric contact structure;
an electrically conductive chip carrier having at least one coupling cavity;
a coupling structure located at least partially in the at least one coupling cavity and electrically contacting the at least one electric contact structure with the chip carrier,
   wherein the at least one electric contact structure comprises a pad and a pillar on the pad.

Aspect 2. The package according to aspect 1, wherein the electronic chip is mounted on the chip carrier in a flip chip configuration.

Aspect 3. The package according to aspect 1, wherein at least part of a surface of the at least one coupling cavity comprises at least one, but not limited to one, of the following surface finishes:
an electric connection-promoting plating;
an electric connection-promoting configuration of a bare metal surface, in particular a bare copper surface;
an electric connection-promoting pre-plating; and
an electric connection-promoting deposited material.

Aspect 4. The package according to aspect 1, comprising an encapsulant, in particular a mold compound, encapsulating at least part of the electronic chip and at least part of the chip carrier.

Aspect 5. The package according to aspect 4, wherein at least part of a surface of the chip carrier encapsulated by the encapsulant is configured to have a higher adhesiveness for material of the encapsulant than an adjacent surface, in particular than a surface of the chip carrier in the at least one coupling cavity.

Aspect 6. The package according to aspect 5, wherein at least part of the surface with the locally higher adhesiveness comprises at least one of the following surface finishes:
an adhesiveness promoting configuration of a bare metal surface, in particular a bare copper surface;
an adhesiveness promoting pre-plating; and
an adhesiveness promoting roughening of the surface.

Aspect 7. The package according to aspect 1, wherein the coupling structure comprises a plated cap integrally formed on the pillar.

Aspect 8. The package according to aspect 1, wherein the pillar is configured without integrated cap.

Aspect 9. The package according to aspect 1, wherein the coupling structure comprises at least one solder bump.

Aspect 10. The package according to aspect 1, wherein the coupling structure located in one coupling cavity electrically contacts at least two separate electrically conductive pillars on a common pad of the at least one electric contact structure.

Aspect 11. The package according to aspect 1, wherein the chip carrier comprises or consists of a leadframe, for example a copper leadframe.

Aspect 12. The package according to aspect 1, further comprising:
a further electronic chip with at least one further electric contact structure;
a further coupling structure located at least partially in at least one further coupling cavity and electrically contacting the at least one further electric contact structure with the chip carrier.

Aspect 13. The package according to aspect 1, wherein the at least one coupling cavity delimits an entirely round surface portion of the chip carrier.

Aspect 14. The package according to aspect 1, wherein the coupling structure comprises at least one of the group consisting of:
a solder structure;
an electrically conductive adhesive; and
a sinter structure.

Aspect 15. A package, comprising:
an electronic chip with at least one electric contact structure;
a chip carrier having a first surface portion being geometrically adapted to have a higher wettability for coupling material than an adjacent surface, and having a second surface portion, having a higher adhesiveness for encapsulant material than an adjacent surface;
a coupling structure located at least partially on the first surface portion and electrically contacting at least one electric contact structure with the chip carrier;
an encapsulant encapsulating at least part of the electronic chip and covering at least part of the second surface portion,
   wherein the at least one electric contact structure comprises a pad and a pillar on the pad.

Aspect 16. The package according to aspect 15, wherein the first surface portion forms at least part of a coupling cavity.

Aspect 17. The package according to aspect 15, wherein the coupling material comprises at least one of the group consisting of:
a solder material;
an electrically conductive adhesive; and
a sinter material.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A method of manufacturing a package, the method comprising:
providing an electronic chip with at least one electric contact structure comprising a pad and a pillar on the pad;
providing an electrically conductive chip carrier with at least one coupling cavity;
coupling a coupling structure at least partially in the at least one coupling cavity to thereby electrically contact the at least one electric contact structure with the chip carrier.

2. The method according to claim 1, wherein the coupling of the coupling structure is performed such that the pillar contacts the coupling structure within the coupling cavity.

3. The method according to claim 1, wherein the pillar is connected to the electronic chip via the pad.

4. The method according to claim 1, wherein the at least one coupling cavity is a concave coupling cavity.

5. The method according to claim 1, wherein the at least one coupling cavity is formed by at least one of the group consisting of etching and stamping the chip carrier.

6. The method according to claim 1, wherein the coupling structure has a larger lateral extension than a corresponding one of the at least one coupling cavity prior to the coupling in the at least one coupling cavity.

7. The method according to claim 1, wherein the method further comprises providing a flux in the at least one coupling cavity for activating a surface of the chip carrier in the at least one coupling cavity prior to coupling the coupling structure in the at least one coupling cavity.

8. The method according to claim 1, wherein the coupling comprises at least one of the group consisting of:
soldering;
adhering an electrically conductive adhesive; and
sintering.

9. The method according to claim 1, wherein the pillar is made of an electrically conductive material.

10. The method according to claim 1, wherein the pillar is made of copper.

11. The method according to claim 1, wherein the chip carrier comprises or consists of a leadframe, for example a copper leadframe.

12. The method according to claim 1, wherein the coupling structure comprises or consists of solderable, sinterable or conductive and adhesive material.

13. The method according to claim 1, wherein the coupling structure comprises or consists of tin.

14. A method of manufacturing a package, the method comprising:
providing an electronic chip with at least one electric contact structure comprising a pad and a pillar on the pad;
providing an electrically conductive chip carrier with a first surface portion being geometrically adapted to have a higher wettability for coupling material than an adjacent second surface portion, and with the second surface portion, having a higher adhesiveness for encapsulant material than the adjacent first surface portion;
coupling a coupling structure at least partially on the first surface portion to thereby electrically contact the at least one electric contact structure with the chip carrier;
encapsulating at least part of the electronic chip and the second surface portion by an encapsulant.

15. The method according to claim 14, wherein the pillar is made of an electrically conductive material.

16. The method according to claim 14, wherein the pillar is made of copper.

17. The method according to claim 14, wherein the chip carrier comprises or consists of a leadframe, for example a copper leadframe.

18. The method according to claim 14, wherein the coupling structure comprises or consists of solderable, sinterable or conductive and adhesive material.

19. The method according to claim 14, wherein the coupling structure comprises or consists of tin.
